(19) United States
(12) Patent Application Publication
(10) Pub. No.: US 2026/0143591 A1
(43) Pub. Date: May 21, 2026

(54) SUBSTRATE STRUCTURE

(71) Applicant: Unimicron Technology Corp., Taoyuan City (TW)

(72) Inventors: Yu-Hua Chen, Hsinchu City (TW); Ra-Min Tain, Hsinchu County (TW)

(73) Assignee: Unimicron Technology Corp., Taoyuan City (TW)

(21) Appl. No.: 19/239,854

(22) Filed: Jun. 16, 2025

Related U.S. Application Data
(60) Provisional application No. 63/721,576, filed on Nov. 18, 2024.
(60) Provisional application No. 63/770,328, filed on Mar. 11, 2025.

(30) Foreign Application Priority Data
May 15, 2025 (TW) 114118207

(51) Int. Cl. H05K 1/11; H05K 3/38

(52) U.S. Cl. CPC H05K 1/116; H05K 3/38

(57) ABSTRACT

A substrate structure including a dielectric substrate, an adhesion promotion layer (APL), a conductive material, at least one dielectric layer and at least one pad. The dielectric substrate has an upper surface and a lower surface opposite to each other, and at least one through-hole passing through the dielectric substrate and connected to the upper surface and the lower surface. The APL is disposed on the upper surface, on the lower surface, and on an inner wall of the through-hole of the dielectric substrate. The conductive material fills the through-hole to define at least one conductive through-hole. The dielectric layer is disposed on the APL and has at least one opening exposing the conductive through-hole. A diameter of the opening is greater than a diameter of the conductive through-hole. The pad is disposed in the opening, extends onto the dielectric layer, and electrically connected to the conductive through-hole.

### CROSS-REFERENCE TO RELATED APPLICATION

This application claims the priority benefit of Taiwan application serial no. 114118207, filed on May 15, 2025, U.S. provisional application Ser. No. 63/770,328, filed on Mar. 11, 2025 and U.S. provisional application Ser. No. 63/721,576, filed on Nov. 18, 2024. The entirety of each of the above-mentioned patent applications is hereby incorporated by reference herein and made a part of this specification.

### BACKGROUND

### Technical Field

The disclosure relates to a substrate structure, and more particularly to a substrate structure having improved structural reliability.

### Description of Related Art

Currently, a semi-additive process (SAP) is adopted to fabricate a metal pad outside a conductive through-hole of glass, wherein the metal pad is directly connected to the conductive through-hole and directly contacts a glass substrate. However, an undercut is generated at a contact angle between an edge of the metal pad and the glass, which is a stress concentration region and easily causes glass breakage, thereby affecting structural reliability of a product.

### SUMMARY

The disclosure provides a substrate structure having improved structural reliability.

A substrate structure of the disclosure includes a dielectric substrate, an adhesion promotion layer, a conductive material, at least one dielectric layer, and at least one pad. The dielectric substrate has an upper surface and a lower surface opposite to each other and at least one through-hole passing through the dielectric substrate and connected to the upper surface and the lower surface. The adhesion promotion layer is disposed on the upper surface, on the lower surface, and on an inner wall of the at least one through-hole of the dielectric substrate. The conductive material fills the at least one through-hole to define at least one conductive through-hole. The at least one dielectric layer is disposed on the adhesion promotion layer and has at least one opening exposing the at least one conductive through-hole. A diameter of the at least one opening is greater than a diameter of the at least one conductive through-hole. The at least one pad is disposed in the at least one opening of the at least one dielectric layer and extends onto the at least one dielectric layer. The at least one pad is electrically connected to the at least one conductive through-hole.

In an embodiment of the disclosure, the at least one pad includes a seed layer and a metal layer. The seed layer covers an inner wall of the at least one opening and extends onto the at least one dielectric layer, and the metal layer is disposed on the seed layer.

In an embodiment of the disclosure, a top surface of the at least one conductive through-hole is flush with a surface of the adhesion promotion layer relatively away from the dielectric substrate.

In an embodiment of the disclosure, a material of the dielectric substrate includes an inorganic material or a non-conductive composite material.

In an embodiment of the disclosure, a material of the adhesion promotion layer includes an oxide or a nitride.

In an embodiment of the disclosure, a thickness of the adhesion promotion layer is between 0.01 nanometers and 100 nanometers.

In an embodiment of the disclosure, an adhesion force between the at least one pad and the at least one dielectric layer is greater than an adhesion force between the at least one pad and the adhesion promotion layer.

In an embodiment of the disclosure, a Young's modulus of the at least one dielectric layer is less than a Young's modulus of the dielectric substrate.

In an embodiment of the disclosure, a material of the at least one dielectric layer includes an organic material or an inorganic material.

In an embodiment of the disclosure, no undercut is provided between the at least one pad and the dielectric substrate.

Based on the above, in the design of the substrate structure of the disclosure, the adhesion promotion layer is disposed on the upper surface, on the lower surface, and on an inner wall of the through-hole of the dielectric substrate, the dielectric layer is disposed on the adhesion promotion layer, and the pad is disposed in the opening of the dielectric layer and extends onto the dielectric layer. That is, the dielectric layer and/or the adhesion promotion layer is interposed between the pad and the dielectric substrate, so that no undercut is generated between the pad and the dielectric substrate. Therefore, the substrate structure of the disclosure has improved structural reliability.

To make the features and advantages of the disclosure more comprehensible, several embodiments accompanied with drawings are described in detail as follows.

### BRIEF DESCRIPTION OF THE DRAWINGS

FIGS. 1A to 1I are cross-sectional schematic diagrams of a method for fabricating a substrate structure according to an embodiment of the disclosure.

### DESCRIPTION OF THE EMBODIMENTS

The embodiments of the disclosure can be understood together with the drawings, and the drawings of the disclosure are also regarded as a part of the disclosure description. It is to be understood that the drawings of the disclosure are not to scale and, in fact, the dimensions of elements may be arbitrarily enlarged or reduced in order to clearly represent the features of the disclosure.

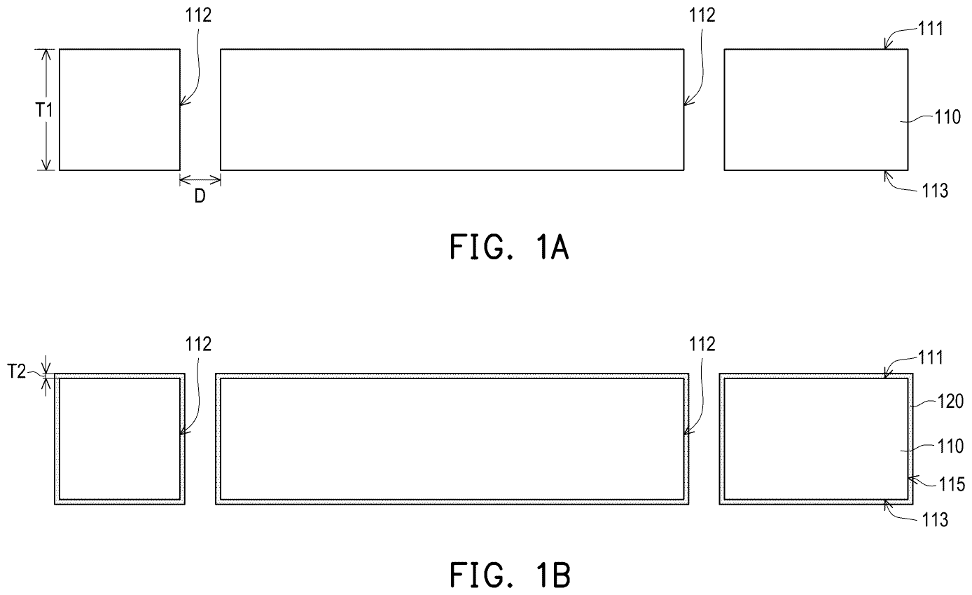

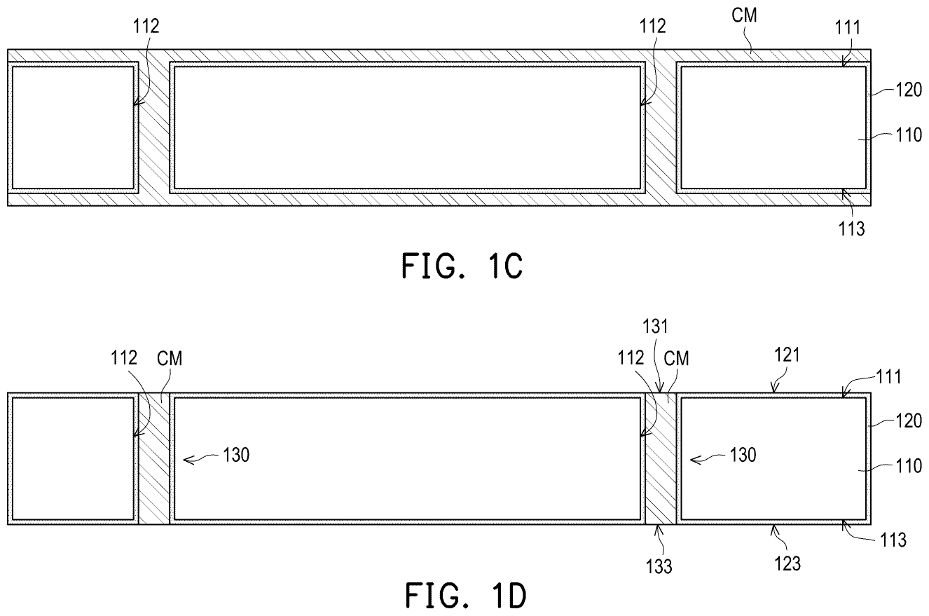

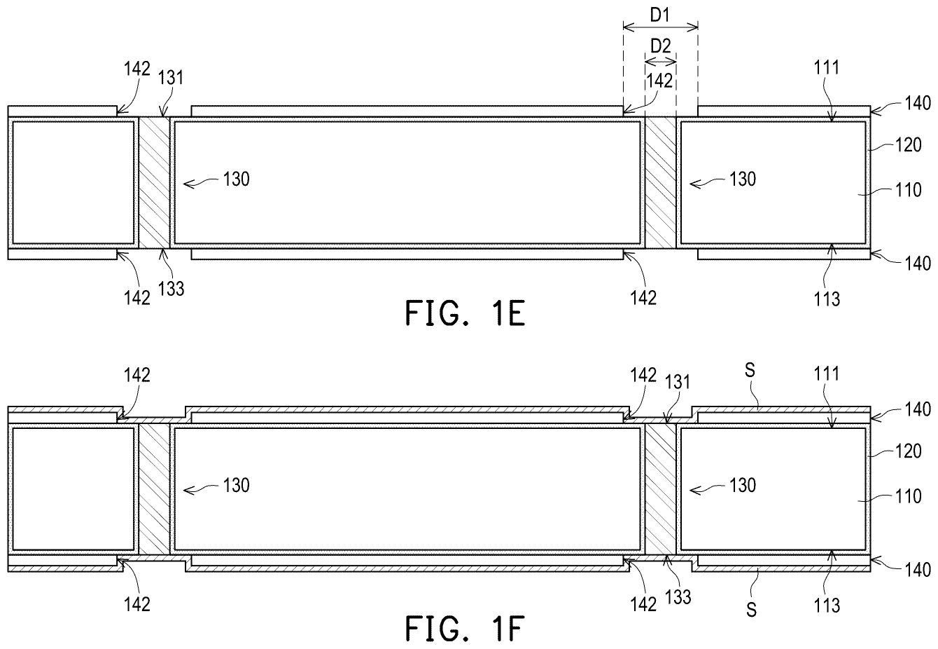

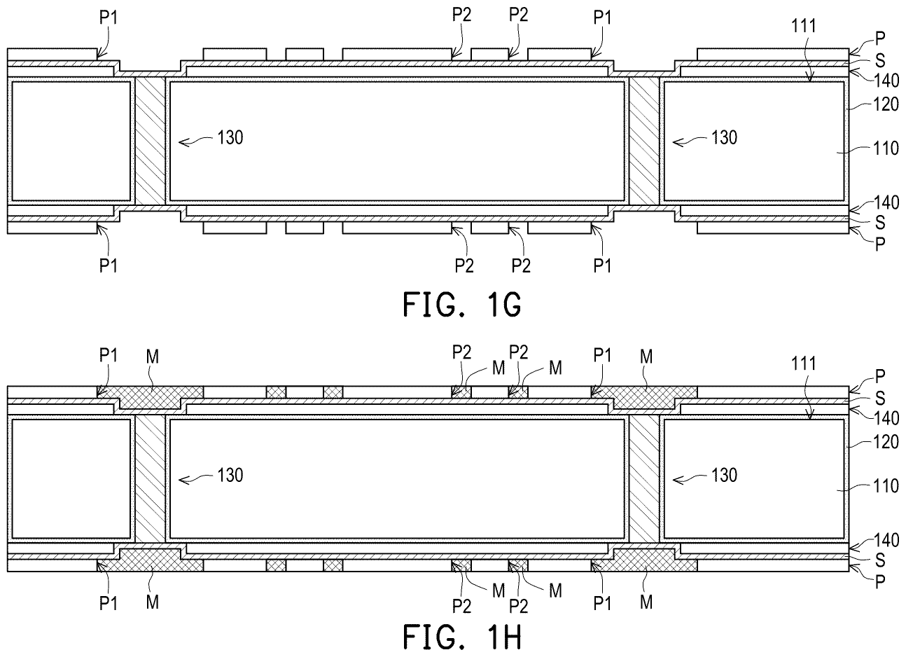

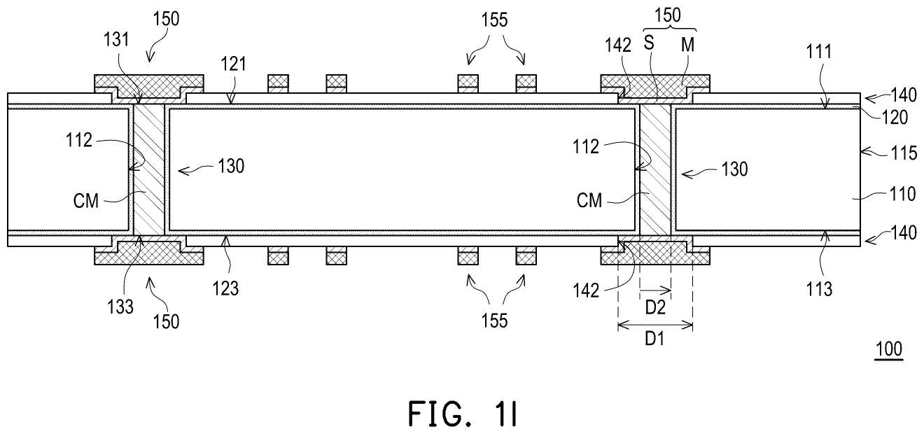

FIGS. 1A to 1I are cross-sectional schematic diagrams of a method for fabricating a substrate structure according to an embodiment of the disclosure.

According to a method for fabricating the substrate structure of this embodiment, first, referring to FIG. 1A, a dielectric substrate 110 is provided. The dielectric substrate 110 has an upper surface 111 and a lower surface 113 opposite to each other and at least one through-hole (two through-holes 112 are schematically illustrated) passing through the dielectric substrate 110 and connected to the upper surface 111 and the lower surface 113. In an embodiment, a material of the dielectric substrate 110 includes an inorganic material or a non-conductive composite material. In an embodiment, the inorganic material is, for example, glass, ceramic, or glass ceramic. In this embodiment, a surface roughness such as an arithmetic average roughness (Ra) of the dielectric substrate 110 is less than 10 nanometers. A thickness T1 of the dielectric substrate 110 is, for example, between 10 micrometers and 400 micrometers. In an embodiment, the through-hole 112 may be a through-glass via (TGV), wherein a diameter D of the through-hole 112 is, for example, between 20 micrometers and 150 micrometers.

Next, referring to FIG. 1B, an adhesion promotion layer 120 is formed on the upper surface 111, on the lower surface 113, and on an inner wall of the through-hole 112 of the dielectric substrate 110 by a dry deposition method, but not limited thereto. Here, the adhesion promotion layer 120 is completely covered on the upper surface 111, on the lower surface 113, on a surrounding surface 115 connecting the upper surface 111 and the lower surface 113, and on the inner wall of the through-hole 112 of the dielectric substrate 110. In an embodiment, a material of the adhesion promotion layer 120 is, for example, an oxide or a nitride, wherein the oxide is, for example, titanium oxide (TiO_{X}) (such as titanium monoxide (TiO) or titanium dioxide (TiO₂)), silicon oxide (SiO_{X}) (such as silicon dioxide (SiO₂)), or aluminum oxide (Al₂O₃), and the nitride is, for example, silicon nitride (SiN_{X}) (such as silicon nitride (Si₃N₄)). In this embodiment, a thickness T2 of the adhesion promotion layer 120 is, for example, between 0.01 nanometers and 100 nanometers, wherein the adhesion promotion layer 120 can increase an adhesion force between the dielectric substrate 110 and a metal layer to be subsequently formed.

Next, referring to FIG. 1C, a conductive material CM is formed on the adhesion promotion layer 120 and fills the through-hole 112 by an electroplating method, wherein the conductive material CM covers the adhesion promotion layer 120 located on the upper surface 111 and the lower surface 113 of the dielectric substrate 110. In an embodiment, the conductive material CM is, for example, copper or conductive paste.

Next, referring to FIGS. 1C and 1D, the conductive material CM located on the upper surface 111 and the lower surface 113 of the dielectric substrate 110 is removed through a chemical-mechanical-polishing process so as to define at least one conductive through-hole (two conductive through-holes 130 are schematically illustrated) in the through-hole 112. In an embodiment, a top surface 131 and a bottom surface 133 of the conductive through-holes 130 opposite to each other are respectively flush with surfaces 121 and 123 of the adhesion promotion layer 120 relatively away from the dielectric substrate 110.

Next, referring to FIG. 1E, at least one dielectric layer (two dielectric layers 140 are schematically illustrated) is disposed on the adhesion promotion layer 120 and has at least one opening (a plurality of openings 142 are schematically illustrated) exposing the conductive through-hole 130. The dielectric layers 140 are respectively disposed on the upper surface 111 and the lower surface 113 of the dielectric substrate 110. The dielectric layer 140 directly contacts the adhesion promotion layer 120, and a diameter D1 of the opening 142 is greater than a diameter D2 of the corresponding conductive through-hole 130. That is, the opening 142 of the dielectric layer 140 exposes the top surface 131 and the bottom surface 133 of the conductive through-hole 130 and a portion of the adhesion promotion layer 120. In an embodiment, a Young's modulus of the dielectric layer 140 is less than a Young's modulus of the dielectric substrate 110. In an embodiment, a material of the dielectric layer 140 is, for example, an organic material or an inorganic material. In an embodiment, a material of the dielectric layer 140 is, for example, an Ajinomoto Build-up Film (ABF), silicon oxide, silicon nitride, or photoresist material.

Next, referring to FIG. 1F, a seed layer S is formed on the dielectric layer 140, wherein the seed layer S covers the dielectric layer 140 and an inner wall of the opening 142, and directly contacts a top surface 131 and a bottom surface 133 of the conductive through-hole 130.

Next, referring to FIG. 1G, a patterned photoresist layer P is formed on the seed layer S, wherein the patterned photoresist layer P has a plurality of first openings P1 and a plurality of second openings P2. The first opening P1 and the second opening P2 expose a part of the seed layer S, and the first opening P1 corresponds to the conductive through-hole 130. In an embodiment, the first opening P1 is greater than the second opening P2. In an embodiment, a vertical projection of the first opening P1 on the dielectric substrate 110 is greater than the conductive through-hole 130, and the conductive through-hole 130 is located within the vertical projection of the first opening P1.

Next, referring to FIG. 1H, a metal layer M is formed on the seed layer S exposed by the patterned photoresist layer P by an electroplating method, wherein the metal layer M is located in and fills the first opening P1 and the second opening P2.

Afterwards, referring to FIGS. 1H and 1I, the patterned photoresist layer P and the seed layer S under the patterned photoresist layer P are removed, and a pad 150 and a trace 155 are formed on the dielectric layer 140. Here, the pad 150 corresponds to the conductive through-hole 130 and includes the seed layer S and the metal layer M, wherein the seed layer S covers an inner wall of the opening 142 of the dielectric layer 140 and extends onto the dielectric layer 140, and the metal layer M is disposed on the seed layer S. The trace 155 includes the seed layer S and the metal layer M. That is, the pad 150 and the trace 155 of this embodiment are both two-layer structures and are fabricated by a dual damascene method. Afterwards, a singulation cutting process is performed so that an edge of the dielectric layer 140, an edge of the adhesion promotion layer 120, and a surrounding surface 115 of the dielectric substrate 110 are flush with each other. Up to this point, the fabrication of a substrate structure 100 is completed.

In terms of structure, referring again to FIG. 1I, in this embodiment, the substrate structure 100 includes the dielectric substrate 110, the adhesion promotion layer 120, the conductive material CM, the dielectric layer 140, and the pad 150. The dielectric substrate 110 has an upper surface 111 and a lower surface 113 opposite to each other and a through-hole 112 passing through the dielectric substrate 110 and connected to the upper surface 111 and the lower surface 113. The adhesion promotion layer 120 is disposed on the upper surface 111, on the lower surface 113, and on an inner wall of the through-hole 112 of the dielectric substrate 110. That is, the adhesion promotion layer 120 does not cover a surrounding surface 115 of the dielectric substrate 110. The conductive material CM fills the through-hole 112 to define the conductive through-hole 130. A top surface 131 and a bottom surface 133 of the conductive through-hole 130 are respectively flush with surfaces 121 and 123 of the adhesion promotion layer 120 relatively away from the dielectric substrate 110. The dielectric layer 140 is disposed on the adhesion promotion layer 120 and has an opening 142 exposing the conductive through-hole 130. A diameter D1 of the opening 142 is greater than a diameter D2 of the conductive through-hole 130. A Young's modulus of the dielectric layer 140 is less than a Young's modulus of the dielectric substrate 110. The pad 150 is disposed in the opening 142 of the dielectric layer 140 and extends onto the dielectric layer 140, wherein the pad 150 is electrically connected to the conductive through-hole 130. An adhesion force between the pad 150 and the dielectric layer 140 is greater than an adhesion force between the pad 150 and the adhesion promotion layer 120. Therefore, no undercut is provided between the pad 150 and the dielectric substrate 110. In an embodiment, an undercut may only occur at a contact angle between an edge of the pad 150 and the dielectric layer 140, and the dielectric layer 140 and/or the adhesion promotion layer 120 located above the dielectric substrate 110 can effectively protect the dielectric substrate 110 and improve reliability.

In short, since the dielectric layer 140 and/or the adhesion promotion layer 120 is interposed between the pad 150 and the dielectric substrate 110 in this embodiment, no undercut is generated between the pad 150 and the dielectric substrate 110, that is, no undercut exists. Therefore, the substrate structure 100 of this embodiment can have improved structural reliability.

Based on the above, in the design of the substrate structure of the disclosure, the adhesion promotion layer is disposed on the upper surface, on the lower surface, and on an inner wall of the through-hole of the dielectric substrate, the dielectric layer is disposed on the adhesion promotion layer, and the pad is disposed in the opening of the dielectric layer and extends onto the dielectric layer. That is, the dielectric layer and/or the adhesion promotion layer is interposed between the pad and the dielectric substrate, so that no undercut is generated between the pad and the dielectric substrate. Therefore, the substrate structure of the disclosure can have improved structural reliability.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A substrate structure, comprising:
a dielectric substrate, having an upper surface and a lower surface opposite to each other, and at least one through-hole passing through the dielectric substrate and connected to the upper surface and the lower surface;
an adhesion promotion layer, disposed on the upper surface, on the lower surface, and on an inner wall of the at least one through-hole of the dielectric substrate;
a conductive material, filling the at least one through-hole to define at least one conductive through-hole;
at least one dielectric layer, disposed on the adhesion promotion layer and having at least one opening exposing the at least one conductive through-hole, wherein a diameter of the at least one opening is greater than a diameter of the at least one conductive through-hole; and
at least one pad, disposed in the at least one opening of the at least one dielectric layer and extending onto the at least one dielectric layer, wherein the at least one pad is electrically connected to the at least one conductive through-hole.

2. The substrate structure according to claim 1, wherein the at least one pad comprises a seed layer and a metal layer, the seed layer covers an inner wall of the at least one opening and extends onto the at least one dielectric layer, and the metal layer is disposed on the seed layer.

3. The substrate structure according to claim 1, wherein a top surface of the at least one conductive through-hole is flush with a surface of the adhesion promotion layer relatively away from the dielectric substrate.

4. The substrate structure according to claim 1, wherein a material of the dielectric substrate comprises an inorganic material or a non-conductive composite material.

5. The substrate structure according to claim 1, wherein a material of the adhesion promotion layer comprises an oxide or a nitride.

6. The substrate structure according to claim 1, wherein a thickness of the adhesion promotion layer is between 0.01 nanometers and 100 nanometers.

7. The substrate structure according to claim 1, wherein an adhesion force between the at least one pad and the at least one dielectric layer is greater than an adhesion force between the at least one pad and the adhesion promotion layer.

8. The substrate structure according to claim 1, wherein a Young's modulus of the at least one dielectric layer is less than a Young's modulus of the dielectric substrate.

9. The substrate structure according to claim 1, wherein a material of the at least one dielectric layer comprises an organic material or an inorganic material.

10. The substrate structure according to claim 1, wherein no undercut is provided between the at least one pad and the dielectric substrate.
